(19) United States
(12) Patent Application Publication
(10) Pub. No.: US 2013/0273734 A1
(43) Pub. Date: Oct. 17, 2013

(54) METHOD OF MANUFACTURING METAL SALICIDE LAYERS

(71) Applicants: Tse-Yi LU, Chiayi City (TW); Chih-Ming CHIEN, Hsinchu City (TW); Li-Jen YAO, Keelung City (TW)

(72) Inventors: Tse-Yi LU, Chiayi City (TW); Chih-Ming CHIEN, Hsinchu City (TW); Li-Jen YAO, Keelung City (TW)

(73) Assignee: UNITED MICROELECTRONICS CORP., HSINCHU (TW)

(21) Appl. No.: 13/444,916

(22) Filed: Apr. 12, 2012

(51) Int. Cl. H01L 21/768

(52) U.S. Cl. 438/649; 257/E21.593

(57) ABSTRACT

A method of manufacturing salicide layers includes the following steps. Firstly, a silicon substrate with a patterned stack structure of a silicon layer and a first cap layer sequentially formed thereon is provided. Then, a second cap layer is formed on the exposed silicon substrate. The materials of the first cap layer and the second cap layer are different. Then, the first cap layer is removed to expose the silicon layer. Then, a first metal layer is formed on the silicon layer and reacted with the silicon layer to produce a first salicide layer. Afterward, the second cap layer is removed, and a second metal layer is formed over the surface of the silicon substrate and reacted with the silicon substrate to produce a second salicide layer.

### FIELD OF THE INVENTION

The present invention relates to a method of manufacturing a semiconductor device, and more particularly to a method of manufacturing salicide layers of a semiconductor device.

### BACKGROUND OF THE INVENTION

As the size of the semiconductor device is gradually shortened, it is important to reduce the resistance of the semiconductor device and reduce the junction leakage current in order to increase the response speed (e.g. switching frequency) and reduce power consumption. For achieving the above purposes, a method of forming two salicide layers with different materials or different thicknesses is disclosed. These two salicide layers are located at two different regions of the semiconductor device. For example, two self-aligned salicide layers (also referred as salicide layers) with different thicknesses are respectively formed in the gate region and the source/drain region of a MOS transistor in order to achieve the above purposes. However, the process of forming two salicide layers at two different regions is complicated.

Therefore, there is a need of providing an improved method of manufacturing salicide layers in order to obviate the drawbacks encountered from the prior art.

### SUMMARY OF THE INVENTION

In accordance with an aspect, the present invention provides a method of manufacturing salicide layers in the fabrication of a semiconductor device. The method includes the following steps. Firstly, a silicon substrate with a patterned stack structure of a silicon layer and a first cap layer sequentially formed thereon is provided. Then, a second cap layer is formed on the exposed silicon substrate. The materials of the first cap layer and the second cap layer are different. Then, the first cap layer is removed to expose the silicon layer. Then, a first metal layer is formed on the silicon layer and reacted with the silicon layer to produce a first salicide layer. Afterward, the second cap layer is removed, and a second metal layer is formed over the surface of the silicon substrate and reacted with the silicon substrate to produce a second salicide layer.

In an embodiment, before forming the patterned stack structure, a first dielectric layer is formed over the surface of the silicon substrate.

In an embodiment, before removing the first cap layer, a second dielectric layer is formed over the first cap layer and the patterned stack structure, and a part of the second dielectric layer and a part of the first dielectric layer are then etched back to form a spacer beside the pattern stack structure and a portion of the surface of the silicon substrate is exposed.

In an embodiment, the first dielectric layer is formed by a thermal oxidation process or a chemical vapor deposition process.

In an embodiment, the second dielectric layer is formed of silicon dioxide.

In an embodiment, the first cap layer is formed of silicon nitride.

In an embodiment, before removing the second cap layer, a doped region can be formed in the silicon substrate beside the patterned stack structure. Then, a high-temperature annealing process may be performed to treat the doped region.

In an embodiment, before removing the second cap layer, a doped region is formed in the silicon substrate beside the patterned stack structure and then a high-temperature annealing process to treat the doped region is performed.

In an embodiment, an oxygen gas is further fed in the high-temperature annealing process to form the second cap layer by a thermal oxidation process.

In an embodiment, the method of forming the first salicide layer includes forming a first metal layer on the silicon layer and reacted with each other to form the first salicide layer.

In an embodiment, an annealing process is performed twice after forming the first metal layer.

In an embodiment, the method of forming the second salicide layer includes forming a second metal layer on the silicon substrate and reacted with each other to form the second salicide layer.

In an embodiment, an annealing process is performed twice after forming the second metal layer.

In an embodiment, a thickness of the second salicide metal layer is different from that of the first metal salicide layer.

In an embodiment, a thickness of the second salicide metal layer is smaller than that of the first salicide metal layer.

### BRIEF DESCRIPTION OF THE DRAWINGS

The above objects and advantages of the present invention will become more readily apparent to those ordinarily skilled in the art after reviewing the following detailed description and accompanying drawings, in which:

FIGS. 1A˜1G are schematic cross-sectional views illustrating a method of manufacturing salicide layers in the fabrication of a MOSFET device according to another embodiment of the present invention.

### DETAILED DESCRIPTION OF PREFERRED EMBODIMENTS

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

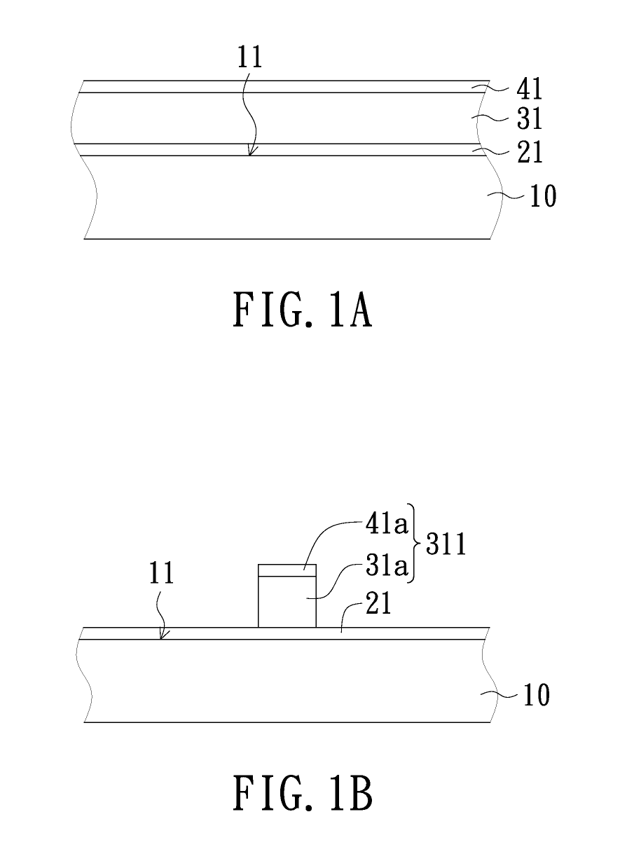

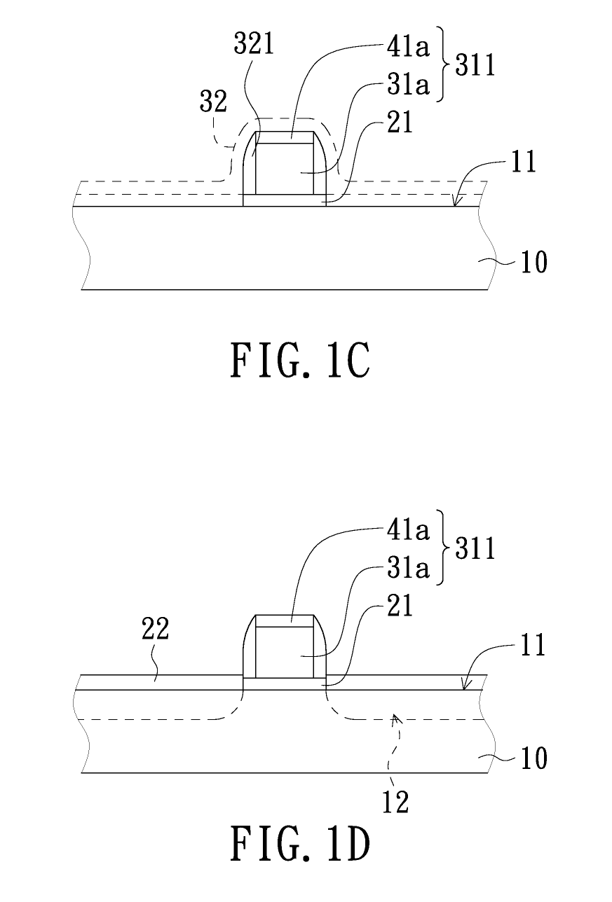

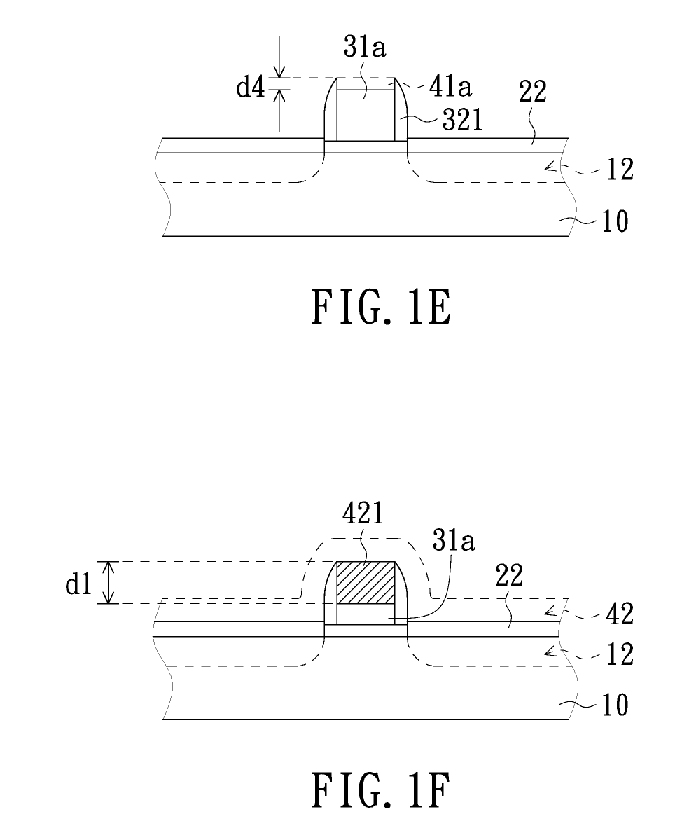

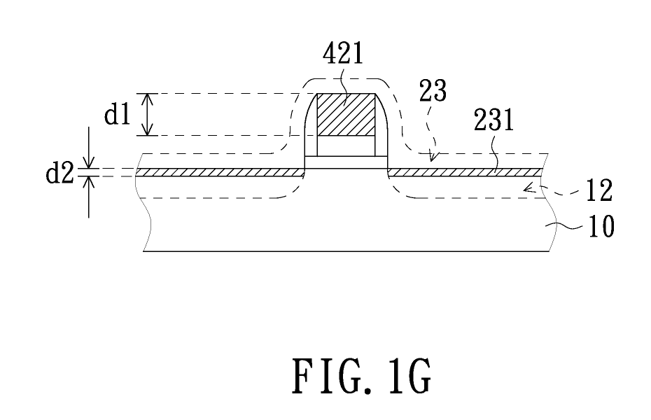

FIGS. 1A˜1G are schematic cross-sectional views illustrating a method of manufacturing salicide layers in the fabrication of a MOSFET device according to another embodiment of the present invention. In this embodiment, a first cap layer is made of silicon nitride, and a second cap layer is made of silicon dioxide. Moreover, the materials of the first cap layer and the second cap layer are not restricted as long as a high etching selectivity ratio of the first cap layer to the second cap layer is achieved.

Firstly, as shown in FIG. 1A and FIG. 1B, a first dielectric layer 21 is formed on a silicon substrate 10. For example, the first dielectric layer 21 is a silicon dioxide layer, which is formed on the surface of the silicon substrate 10 by a thermal oxidation process. Alternately, the first dielectric layer 21 also can be formed by performing chemical vapor deposition process to deposit silicon dioxide or other dielectric material, such as silicon nitride, silicon oxynitride, high-K dielectric materials, like hafnium oxide or zirconium oxide, or the combination thereof. Then, a patterned stack structure 311 is formed on the first dielectric layer 21. In this embodiment, the method of forming the patterned stack structure 311 includes the following steps. Firstly, a polysilicon layer 31 and a silicon nitride layer 41 are sequentially formed on the first dielectric layer 21. Then, a photolithography and etching process is performed to pattern the polysilicon layer 31 to a silicon layer 31a and to pattern the silicon nitride layer 41 to a first cap layer 41a by using the first dielectric layer 21 as an etch stop layer. The silicon layer 31a and the first cap layer 41a are stacked to form the pattern stack structure 311. It should be noted that the first cap layer is made of silicon nitride for protecting the underlying silicon layer 31a from being reacted with oxygen to produce silicon dioxide at high temperature.

In other embodiments, the first dielectric layer 21 exposed by the stack structure 311 also can be removed to expose a portion of the surface 11 of the substrate 10 beside the stack structure 311.

Then, as shown in FIG. 1C, a second dielectric layer 32 is formed over the first dielectric layer 21 and the patterned stack structure 311. For example, the second dielectric layer 32 is also a silicon dioxide layer. Then, an anisotropic etching process is performed to etch back and partially remove a part of the second dielectric layer 32 and a part of the first dielectric layer 21, so that a spacer 321 is formed beside the patterned stack structure 311 and a portion of the surface 11 is exposed.

Then, as shown in FIG. 1D, an ion implantation process is performed by using the patterned stack structure as an implantation mask, so that a doped region 12 is formed. Then, a high-temperature annealing process is performed to treat the doped region 12 and a second cap layer 22 is formed on the exposed portion of the surface 11 of the silicon substrate 10. In this embodiment, during the high-temperature annealing process is performed, oxygen gas is fed for performing a thermal oxidation process to form a silicon dioxide layer as the second cap layer 22. The second cap layer is made of silicon dioxide for protecting the silicon substrate 10 from being reacted with a subsequently-formed first metal layer to produce salicide at high temperature.

Then, as shown in FIG. 1E, relying on an etching selectivity ratio of the first cap layer 41a to the second cap layer 22 with respective to a specific etch recipe, the first cap layer 41a is selectively etched but the second cap layer 22 is retained. In this embodiment, the etching selectivity ratio of the first cap layer 41a (e.g. a silicon nitride layer) to the second cap layer 22 (e.g. a silicon dioxide layer) with respective to an acidic etchant solution is vey high. After the selective etching process is done, the silicon nitride layer is completely removed, but the silicon dioxide layer is retained. As shown in FIG. 1E, after the selective etching process is performed to remove the first cap layer 41a, the surface of the exposed silicon layer 31a is slightly lower than the spacer 321 by a height difference d4.

Then, as shown in FIG. 1F, a first metal layer 42 is formed over the resulting structure of FIG. 1E. In an embodiment, the material of the first metal layer 42 is titanium (Ti), cobalt (Co), nickel (Ni), palladium, (Pd) or platinum (Pt) or any combination thereof. The first metal layer 42 and the exposed silicon layer 31a are reacted to produce a first salicide layer 421. In this embodiment, a first annealing process is performed so that the first metal layer 42 is reacted with the silicon layer 31a to product salicide layer. Next, the portions of the first metal layer 42 which are not contacted with the silicon layer 31a or not reacted with silicon layer 31a are removed. Then, a second annealing process is performed to transform the resulting salicide layer to the first salicide layer 421 with lower low resistivity. Meanwhile, the first salicide layer 421 has a thickness d1.

As known, in the conventional method of fabricating a MOSFT device, the polysilicon layer at the top surface of gate electrode is at the same level as the top surface of the spacer. Whereas, according to the present invention, after the selective etching process is performed, the surface of the silicon layer 31a is slightly lower than the spacer 321 by a height difference d4 (see FIG. 1E). Due to the height difference, the top surface of the polysilicon layer 31a can receive more first metal layer 42. Consequently, a thicker first salicide layer 421 is produced to reduce the resistance and increase the response speed of the semiconductor device.

After the step of FIG. 1F is done, the second cap layer 22 is removed, and then a second metal layer 23 is formed, as shown in FIG. 1G. The second metal layer 23 and the exposed portion of the silicon substrate 10 are reacted to produce a second salicide layer 231. Next, the portions of the second metal layer 23 which are not contacted with the silicon substrate 10 are removed. In this embodiment, the material of the second metal layer 23 is titanium (Ti), cobalt (Co), nickel (Ni), palladium, (Pd) or platinum (Pt) or any combination thereof. After forming the second metal layer 23, annealing process is also performed twice to make the second metal layer 23 react with the exposed portion of the silicon substrate 10 for producing the second salicide layer 231. Specially, the second annealing process of the first salicide layer 421 can be skipped and done by the second annealing process of the second salicide layer 231.

It is noted that the first metal layer 42 and the second metal layer 23 may be made of different materials. Further, the first metal layer 42 should be capable of bearing higher temperature than the second metal layer 23 to prevent the first metal layer 42 from being damaged during the process of forming the second metal layer 23. Moreover, for increasing the response speed of the semiconductor device and reducing the junction leakage current, it is preferred that the thickness of the second metal layer 23 is smaller than the thickness of the first metal layer 42. Consequently, after the reaction is carried out, the thickness d2 of the second salicide layer 231 is, for example, smaller than the thickness dl of the first salicide layer 421.

From the above description, the method of the present invention is capable of forming two salicide layers with different materials or different thicknesses at two different region of a semiconductor device by using reduced number of photolithography and etching processes. Consequently, the purposes of increasing the response speed of the semiconductor device and reducing the junction leakage current are both achieved. That is, the fabricating cost is reduced, and the size of the semiconductor device is reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A method of manufacturing salicide layers in fabrication of a semiconductor device, the method comprising steps of:
providing a silicon substrate with a patterned stack structure of a silicon layer and a cap layer sequentially formed on a surface thereof;
forming a second cap layer on the exposed silicon substrate, wherein the second cap layer and the first cap layer are made of different materials;
removing the first cap layer to expose the silicon layer;
forming a first salicide layer on the silicon layer; and
removing the second cap layer to expose a portion of the surface; and
forming a second salicide layer over the exposed portion of the surface of the silicon substrate.

2. The method according to claim 1, further comprising the step of forming a first dielectric layer over the surface of the silicon substrate prior to forming the patterned stack structure.

3. The method according to claim 2, further comprising the steps of prior to removing the first cap layer:
forming a second dielectric layer over the first dielectric layer and the patterned stack structure; and
etching back and removing a part of the second dielectric layer and a part of the first dielectric layer to form a spacer beside the patterned stack structure and to expose a portion of the surface of the silicon substrate.

4. The method according to claim 2, wherein the method of forming the first dielectric layer comprises a thermal oxidation process or a chemical vapor deposition.

5. The method according to claim 3, wherein the material of the second dielectric layer comprises silicon dioxide.

6. The method according to claim 1, wherein the material of the first cap layer comprises silicon nitride layer.

7. The method according to claim 1, further comprising steps of prior to removing the second cap layer:
forming a doped region in the silicon substrate beside the patterned stack structure; and
performing a high-temperature annealing process to treat the doped region.

8. The method according to claim 7, further comprising feeding oxygen gas in the high-temperature annealing process to form the second cap layer by a thermal oxidation process.

9. The method according to claim 1, wherein the method of forming the first salicide layer comprises forming a first metal layer on the silicon layer and reacted with each other to form the first salicide layer.

10. The method according to claim 9, further comprising performing annealing process twice after forming the first metal layer.

11. The method according to claim 1, wherein the method of forming the second salicide layer comprises forming a second metal layer on the surface of the silicon substrate and reacted with each other to form the second salicide layer.

12. The method according to claim 11, further comprising performing annealing process twice after forming the second metal layer.

13. The method according to claim 1, wherein a thickness of the second salicide layer is different from that of the first salicide layer.

14. The method according to claim 13, wherein a thickness of the second salicide layer is smaller than that of the first salicide layer.
